(19) United States
(12) Patent Application Publication
(10) Pub. No.: US 2015/0068595 A1
(43) Pub. Date: Mar. 12, 2015

(54) GLASS SUBSTRATE FOR Cu-In-Ga-Se SOLAR CELL, AND SOLAR CELL USING SAME

(71) Applicant: Asahi Glass Company, Limited, Tokyo (JP)

(72) Inventors: Yutaka Kuroiwa, Tokyo (JP); Shinichi Amma, Tokyo (JP); Reo Usui, Tokyo (JP); Tomomi Abe, Tokyo (JP); Takeshi Tomizawa, Tokyo (JP)

(73) Assignee: Asahi Glass Company, Limited, Tokyo (JP)

(21) Appl. No.: 14/480,200

(22) PCT Filed: Mar. 5, 2013
(86) PCT No.: PCT/JP2013/056000

§ 371 Date: Sep. 8, 2014

(30) Foreign Application Priority Data
Mar. 7, 2012 (JP) 2012-050060

(51) Int. Cl. H01L 31/048; C03C 3/093; H01L 31/032

(52) U.S. Cl. CPC H01L 31/0488; H01L 31/0322; C03C 3/093
USPC 136/256; 501/67

(57) ABSTRACT

A glass substrate for a Cu—In—Ga—Se solar cell. The glass substrate includes the specific amounts of SiO₂, Al₂O₃, B₂O₃, MgO, CaO, SrO, BaO, ZrO₂, Na₂O and K₂O. In the glass substrate, MgO+CaO+SrO+BaO is from 10 to 30%, Na₂O+K₂O is from 8 to 20%, Na₂O/K₂O is from 0.7 to 2.0, and (2×Na₂O-2×MgO—CaO)×(Na₂O/K₂O) is from 3 to 22. The glass substrate has a glass transition temperature of from 640 to 700° C., an average coefficient of thermal expansion of from 60×10⁻⁷ to 110×10⁻⁷/° C., and a density of from 2.45 to 2.9 g/cm³.

### TECHNICAL FIELD

The present invention relates to a glass substrate for a solar cell having a photoelectric conversion layer formed between glass substrates, and solar cells using the same. In more detail, the present invention relates to a glass substrate for a Cu—In—Ga—Se solar sell typically having, as a glass substrate, a glass substrate and a cover glass, in which a photoelectric conversion layer containing an element of Group 11, Group 13 or Group 16 as a main component is formed on/above the glass substrate, and a solar cell using the same.

### BACKGROUND ART

Group 11-13 and Group 11-16 compound semiconductors having a chalcopyrite structure and Group 12-16 compound semiconductors of a cubic system or hexagonal system have a large absorption coefficient to light in the visible to near-infrared wavelength range. Thus, they are expected as a material for high-efficiency thin film solar cell. Representative examples thereof include Cu(In,Ga)Se₂ (hereinafter referred to as “CIGS” or “Cu—In—Ga—Se”) and CdTe.

In the CIGS thin film solar cell (hereinafter referred to as “CIGS solar cell”), in view of the matters that it is inexpensive and its average coefficient of thermal expansion is close to that of the CIGS compound semiconductor, a soda lime glass is used as a substrate, and a solar cell is obtained.

Also, in order to obtain a solar cell with good efficiency, a glass material which withstands a heat treatment at a high temperature has been proposed (see Patent Documents 1 to 5).

### PRIOR ART DOCUMENTS

### Patent Document

Patent Document 1: JP-A-11-135819
Patent Document 2: JP-A-2010-118505
Patent Document 3: JP-A-8-290938
Patent Document 4: JP-A-2008-280189
Patent Document 5: JP-A-2010-267965

### SUMMARY OF THE INVENTION

### Problems to be Solved by the Invention

A CIGS photoelectric conversion layer (hereinafter referred to as “CIGS layer”) is formed on/above the glass substrate. However, as disclosed in Patent Document 1, in order to fabricate a solar cell with good cell efficiency, a heat treatment at a higher temperature is preferable, and the glass substrate is required to withstand a heat treatment at a high temperature and satisfy a prescribed average coefficient of thermal expansion. In Patent Document 1, a glass composition having a relatively high annealing point has been proposed. However, it is not always said that the invention described in Patent Document 1 achieves high cell efficiency.

In the inventions described in Patent Documents 2 and 4, a glass for a solar cell having high strain point and satisfying a prescribed average coefficient of thermal expansion has been proposed. However, the problem of Patent Document 2 is to secure heat resistance and improve productivity, and the problem of Patent Document 4 is to enhance surface quality and improve devitrification resistance. Thus, those patent documents do not solve the problem relating to cell efficiency. For this reason, it is not always said that the inventions described in Patent Documents 2 and 4 achieve high cell efficiency.

Furthermore, in Patent Document 3, a high strain point glass substrate close to that in Patent Document 2 has been proposed. However, this proposal focuses on use in a plasma display. Thus, the problem differs, and it is not always said that the invention described in Patent Document 3 achieves high cell efficiency.

Moreover, in Patent Document 4, a glass containing a large amount of boron oxide, having high strain point and satisfying a prescribed average coefficient of thermal expansion has been proposed. However, when a large amount of boron is present in a glass, there is a concern that boron diffuses in a CIGS layer as a p-type semiconductor and acts as a donor, thereby decreasing cell efficiency, as described in Patent Document 5. Moreover, there was a problem that removal facilities of boron are necessary, and this apt to increase costs.

In Patent Document 5, boron in the glass is reduced. However, in the case of the glass composition specifically described, cell efficiency is insufficient, and improvement is required in further enhancement of cell efficiency.

Thus, in the glass substrate used in the CIGS solar cell, it was difficult to have characteristics of high cell efficiency, high glass transition temperature, a prescribed average coefficient of thermal expansion, meltability and formability during production of a sheet glass, and prevention of devitrification in good balance.

An object of the present invention is to provide a glass substrate for a Cu—In—Ga—Se solar cell, having the characteristics of high cell efficiency, high glass transition temperature, a prescribed average coefficient of thermal expansion, meltability and formability during production of a sheet glass, and prevention of devitrification in good balance, and a solar cell using the same.

### Means for Solving the problems

As a result of earnest investigations to solve the above problems, the present inventors have found that in the glass substrate for a Cu—In—Ga—Se solar cell, when the glass substrate has a specific composition, a glass substrate for a Cu—In—Ga—Se solar cell, having the characteristics of high cell efficiency, high glass transition temperature, a prescribed average coefficient of thermal expansion, meltability and formability during production of a sheet glass, and prevention of devitrification in good balance can be obtained.

That is, the present invention provides a glass substrate for a Cu—In—Ga—Se solar cell, comprising, in terms of mass % on the basis of the following oxides:

from 45 to 70% of SiO₂;

from 11 to 20% of Al₂O₃;

0.5% or less of B₂O₃;

from 0 to 6% of MgO;

from 4 to 12% of CaO;

from 5 to 20% of SrO;

from 0 to 6% of BaO;

from 0 to 8% of ZrO₂;

from 4.5 to 10% of Na₂O; and

from 3.5 to 15% of K₂O;

wherein MgO+CaO+SrO+BaO is from 10 to 30%,

Na₂O+K₂O is from 8 to 20%,

Na₂O/K₂O is from 0.7 to 2.0,

(2×Na₂O (content mass %)−2×MgO (content mass %)−CaO (content mass %))×(Na₂O (content mass %)/K₂O (content mass %)) is from 3 to 22, and

the glass substrate has a glass transition temperature of from 640 to 700° C., an average coefficient of thermal expansion of from 60×10⁻⁷ to 110×10⁻⁷/° C., and a density of from 2.45 to 2.9 g/cm³.

In the glass substrate for a Cu—In—Ga—Se solar cell according to the present invention, it is preferred that Na₂O/K₂O is from 0.9 to 1.7, and (2×Na₂O (content mass %)−2×MgO (content mass %)−CaO (content mass %))×(Na₂O (content mass %)/K₂O (content mass %)) is from 5 to 12.

In the glass substrate for a Cu—In—Ga—Se solar cell according to the present invention, it is preferred that the glass substrate has a temperature (T₄) at which a viscosity reaches 10⁴ dPa·s of 1,230° C. or lower, a temperature (T₂) at which a viscosity reaches 10² dPa·s of 1,620° C. or lower, and the relationship between the temperature T₄ and a devitrification temperature (T_{L}) of T₄−T_{L}≧−30° C.

In addition, the present invention provides the solar cell using the same.

### Advantages of the Invention

The glass substrate for a Cu—In—Ga—Se solar cell of the present invention can have the characteristics of high cell efficiency, high glass transition temperature, a prescribed average coefficient of thermal expansion, meltability and formability during production of a sheet glass, and prevention of devitrification in good balance, and can provide a solar cell having high cell efficiency by using the glass substrate for a CIGS solar cell of the present invention.

### BRIEF DESCRIPTION OF THE DRAWINGS

FIG. 1 is a cross-sectional view schematically showing an example of embodiments of a solar cell using the glass substrate for a CIGS solar cell of the present invention.

FIG. 2A shows a solar cell prepared on a glass substrate for evaluation in Examples.

FIG. 2B is a cross-sectional view along A-A′ line of the solar cell shown in FIG. 2A.

FIG. 3 shows a CIGS solar cell for evaluation on a glass substrate for evaluation, where eight pieces of solar cell shown in FIG. 2A are arranged.

### MODE FOR CARRYING OUT THE INVENTION

### <Glass Substrate for Cu—In—Ga—Se Solar Cell of the Present Invention>

The glass substrate for a Cu—In—Ga—Se solar cell of the present invention will be explained below.

The present invention provides a glass substrate for a Cu—In—Ga—Se solar cell, containing, in terms of mass % on the basis of the following oxides:

from 45 to 70% of SiO₂;

from 11 to 20% of Al₂O₃;

0.5% or less of B₂O₃;

from 0 to 6% of MgO;

from 4 to 12% of CaO;

from 5 to 20% of SrO;

from 0 to 6% of BaO;

from 0 to 8% of ZrO₂;

from 4.5 to 10% of Na₂O; and

from 3.5 to 15% of K₂O;

wherein MgO+CaO+SrO+BaO is from 10 to 30%,

Na₂O+K₂O is from 8 to 20%,

Na₂O/K₂O is from 0.7 to 2.0,

(2×Na₂O (content mass %)−2×MgO (content mass %)−CaO (content mass %))×(Na₂O (content mass %)/K₂O (content mass %)) is from 3 to 22, and

the glass substrate has a glass transition temperature of from 640 to 700° C., an average coefficient of thermal expansion of from 60×10⁻⁷ to 110×10⁻⁷/° C., and a density of from 2.45 to 2.9 g/cm³.

The Cu—In—Ga—Se will be described as “CIGS” hereinbelow.

The glass transition temperature (Tg) of the glass substrate for a CIGS solar cell of the present invention is 640° C. or higher and 700° C. or lower, and is higher than a glass transition temperature of a soda lime glass. For the purpose of ensuring the formation of a CIGS layer at a high temperature, the glass transition temperature (Tg) is preferably 645° C. or higher, more preferably 650° C. or higher, and still more preferably 655° C. or higher. For the purpose that viscosity during melting is not excessively increased, the glass transition temperature (Tg) is preferably 690° C. or lower. The glass transition temperature (Tg) is more preferably 685° C. or lower, and still more preferably 680° C. or lower.

An average coefficient of thermal expansion within a range of 50 to 350° C. of the glass substrate for a CIGS solar cell of the present invention is from 60×10⁻⁷ to 110×10⁻⁷/° C. When the average coefficient of thermal expansion is less than 60×10⁻⁷/° C. or exceeds 110×10⁻⁷/° C., the difference in thermal expansion between the CIGS layer and the glass substrate is excessively large, and defects such as peeling are easy to occur. The average coefficient of thermal expansion is preferably 65×10⁻⁷/° C. or more, more preferably 70×10⁻⁷/° C. or more, and still more preferably 75×10⁻⁷/° C. or more. In order to reduce warpage by the difference in expansion between an Mo (molybdenum) film as a positive electrode and the glass substrate, the average coefficient of thermal expansion is preferably 100×10⁻⁷/° C. or less, more preferably 95×10⁻⁷/° C. or less, and still more preferably 90×10⁻⁷/° C. or less.

In the glass substrate for a CIGS solar cell of the present invention, the relationship between a temperature (T₄) at which a viscosity reaches 10⁴ dPa·s and a devitrification temperature (T_{L}) is T₄−T_{L}≧−30° C. When T₄−T_{L} is lower than −30° C., there is a concern that devitrification is easy to occur during the formation of a sheet glass, and the formation of a glass sheet becomes difficult. T₄−T_{L} is preferably −10° C. or higher, more preferably 10° C. or higher, still more preferably 30° C. or higher, and especially preferably 50° C. or higher. The devitrification temperature used herein means a maximum temperature at which crystals are not precipitated on the glass surface and inside the glass when the glass is maintained at a specific temperature for 17 hours.

Considering formability of a glass sheet, that is, enhancement in flatness and enhancement in productivity, T₄ is preferably 1,230° C. or lower. T₄ is preferably 1,220° C. or lower, more preferably 1,210° C. or lower, still more preferably 1,200° C. or lower, and especially preferably 1,190° C. or lower.

Considering meltability of a glass, that is, enhancement in homogeneity and enhancement in productivity, the glass substrate for a CIGS solar cell of the present invention has a temperature (T₂) at which a viscosity reaches 10² dPa·s of 1,620° C. or lower. T₂ is preferably 1,590° C. or lower, more preferably 1,570° C. or lower, still more preferably 1,560° C. or lower, and especially preferably 1,550° C. or lower.

In the glass substrate for a CIGS solar cell of the present invention, Young's modulus is preferably 77 GPa or more. When the Young's modulus is less than 77 GPa, strain amount under a constant stress is increased, there is a concern that warpage occurs in a production process, which causes problems, and the deposition cannot be normally performed. Furthermore, warpage of product is increased, which is not preferred. The Young's modulus is more preferably 77.5 GPa or more, still more preferably 78 GPa or more, and especially preferably 78.5 GPa or more.

Specific elastic modulus (E/d) obtained by dividing Young's modulus (hereinafter referred to as “E”) by a density (hereinafter referred to as “d”) is preferably 27.5 GPa·cm³/g or more. When the specific elastic modulus (E/d) is smaller than 27.5 GPa·cm³/g, the glass substrate sags by the weight itself during conveying by rollers or in the case of partially supporting, and the glass substrate may not be normally fluidized during the production process. The specific elastic modulus (E/d) is more preferably 28 GPa·cm³/g or more. To achieve the specific elastic modulus of 27.5 GPa·cm³/g or more, a density should be 2.8 g/cm³ or less when the Young's modulus is 77 GPa or more, and a density should be 2.85 g/cm³ or less when the Young's modulus is 79 GPa or more.

The glass substrate for a CIGS solar cell of the present invention has the density of 2.45 g/cm³ or more and 2.9 g/cm³ or less. When the density exceeds 2.9 g/cm³, the weight of a product is increased, which is not preferred. Furthermore, the glass substrate becomes brittle and is easy to be broken, which is not preferred. The density is more preferably 2.85 g/cm³ or less, still more preferably 2.82 g/cm³ or less, and especially preferably 2.8 g/cm³ or less.

When the density is less than 2.45 g/cm³, only a light element having small atomic number can be used as the element constituting the glass substrate, and there is a concern that desired cell efficiency and glass viscosity are not obtained. The density is preferably 2.5 g/cm³ or more, more preferably 2.55 g/cm³ or more, and especially preferably 2.6 g/cm³ or more.

The reasons why the glass substrate for a CIGS solar cell of the present invention is limited to the foregoing composition (hereinafter referred to as a “base composition”) are as follows.

Unless otherwise indicated, the percentage (%) described below means mass %.

The expression “is not substantially contained” in the present invention means that it is not contained except for the case that it is contained as unavoidable impurities originated from raw materials or the like, that is, it is not intentionally incorporated.

SiO₂: SiO₂ is a component for forming a network of glass, and when its content is less than 45 mass %, there is a concern that the heat resistance and chemical durability of the glass substrate are lowered, and the average coefficient of thermal expansion increases. The content is preferably 48% or more, more preferably 50% or more, and still more preferably 52% or more.

However, when the content exceeds 70%, there is a concern that the viscosity of glass at a high temperature increases, and a problem that the meltability is deteriorated is caused. The content is preferably 65% or less, more preferably 60% or less, and still more preferably 58% or less.

Al₂O₃: Al₂O₃ increases the glass transition temperature, enhances the weather resistance (solarization), heat resistance and chemical durability, and increases a Young's modulus. When its content is less than 11%, there is a concern that the glass transition temperature is lowered. Also, there is a concern that the average coefficient of thermal expansion increases. The content is preferably 11.5% or more, more preferably 12% or more, and still more preferably 12.5% or more.

However, when the content exceeds 20%, there is a concern that the viscosity of glass at a high temperature increases, and the meltability is deteriorated. Also, there is a concern that the devitrification temperature increases, and the formability is deteriorated. Also, there is a concern that the cell efficiency is lowered. The content is preferably 18% or less, more preferably 16% or less, still more preferably 15% or less, and especially preferably 14% or less.

B₂O₃: B₂O₃ may be contained up to 0.5% for the purposes of enhancing the meltability or the like. When its content exceeds 0.5%, there is a concern that the glass transition temperature decreases, or the average coefficient of thermal expansion becomes small, and thus, it is not preferable for a process for forming the CIGS layer. In addition, there is a concern that the devitrification temperature is increased to easily cause the devitrification, resulting in difficulty of forming the sheet glass. Furthermore, a large size of removal facilities becomes necessary, and environmental load becomes large, which is not preferred.

Moreover, there is a concern that B (boron) diffuses in the CIGS layer as a p-type semiconductor and acts as a donor, thereby decreasing cell efficiency, which is not preferred. The content is preferably 0.3% or less. It is more preferred that B₂O₃ is not substantially contained.

MgO: MgO may be contained because it has effects of decreasing the viscosity during melting of glass, and promoting melting. Its content is preferably 0.05% or more, more preferably 0.1% or more, and still more preferably 0.2% or more.

However, when the content exceeds 6%, there is a concern that the devitrification temperature increases. Also, there is a concern that the cell efficiency is lowered. The content is preferably 4% or less, more preferably 3% or less, still more preferably 2.5% or less, especially preferably 2.0% or less, still further preferably 1.5% or less, and most preferably 1.0% or less.

CaO: CaO is contained in an amount of 4% or more because it has the effects of decreasing the viscosity during melting of glass, and promoting melting. Its content is preferably 4.5% or more, more preferably 4.8% or more, and still more preferably 5% or more. However, when the content exceeds 12%, there is a concern that the average coefficient of thermal expansion of the glass substrate increases. In addition, there is a concern that Na is hard to move in the glass substrate, and thus, the cell efficiency is lowered. The content is preferably 10% or less, more preferably 8% or less, still more preferably 7% or less, and especially preferably 6% or less.

SrO: SrO is contained in an amount of 5% or more because it has the effects of decreasing the viscosity during melting of glass, maintaining the average coefficient of thermal expansion in a desired value, and promoting melting, and further has the effect of promoting the diffusion of Na in the CIGS layer. Its content is preferably 5.5% or more, more preferably 6% or more, and still more preferably 6.5% or more. However, when SrO is contained in an amount exceeding 20%, there is a concern that the average coefficient of thermal expansion of the glass substrate increases, the density increases, and the glass becomes brittle. The content is preferably 18% or less, more preferably 15% or less, still more preferably 13% or less, and especially preferably 12% or less. The content is still further preferably 10% or less, and most preferably 8% or less.

BaO: BaO can be contained because it has the effects of decreasing the viscosity during melting of glass, and promoting melting. Its content is preferably 0.1% or more, more preferably 0.2% or more, and still more preferably 0.5% or more. However, when BaO is contained in an amount exceeding 6%, there is a concern that the cell efficiency is lowered, the average coefficient of thermal expansion of the glass substrate increases, the density increases, and the glass becomes brittle. In addition, there is a concern that the Young's modulus is decreased. The content is preferably 4% or less, more preferably 3% o less, and still more preferably 2% or less.

ZrO₂: ZrO₂ can be contained because it has the effects of decreasing the viscosity during melting of glass, and promoting melting. However, when ZrO₂ is contained in an amount exceeding 8%, the average coefficient of thermal expansion of the glass substrate decreases, the cell efficiency is lowered, and the devitrification temperature is increased to easily cause the devitrification, resulting in difficulty of forming the sheet glass. Its content is preferably 7% or less, more preferably 6% or less, and still more preferably 5.5% or less. In addition, the content is preferably 0.5% or more, more preferably 1% or more, and still more preferably 1.5% or more.

TiO₂: TiO₂ may be contained in an amount of up to 2% for the purposes of enhancing the meltability, and the like. When its content exceeds 2%, the devitrification temperature is increased to easily cause the devitrification, resulting in difficulty of forming the sheet glass. The content is preferably 1% or less, and more preferably 0.5% or less.

MgO, CaO, SrO and BaO: MgO, CaO, SrO and BaO are contained in an amount of 10% or more in total (MgO+CaO+SrO+BaO) from the standpoints of decreasing the viscosity during melting of glass and promoting melting. The total content of those is preferably 13% or more, more preferably 15% or more, and still more preferably 17% or more. However, when the total content exceeds 30%, there is a concern that the devitrification temperature increases and the formability is deteriorated. For this reason, the total content is preferably 26% or less, more preferably 22% or less, and still more preferably 20% or less.

Na₂O: Na₂O is a component which contributes to an enhancement of the cell efficiency of the CIGS solar cell and is an essential component. Also, Na₂O has the effects of decreasing the viscosity at a melting temperature of glass and making it easy to perform melting, and therefore, it is contained in an amount of from 4.5 to 10%. Na diffuses into the CIGS layer constituted on/above the glass substrate, and enhances the cell efficiency. However, when its content is less than 4.5%, there is a concern that the diffusion of Na into the CIGS layer on/above the glass substrate is insufficient, and the cell efficiency is also insufficient. The content is preferably 5% or more, more preferably 5.5% or more, and still more preferably 5.7% or more.

On the other hand, when the Na₂O content exceeds 10%, the average coefficient of thermal expansion tends to become large, and the glass transition temperature tends to be lowered. Also, the chemical durability is deteriorated. Also, there is a concern that the Young's modulus is decreased. Also, there is a concern that the Mo (molybdenum) film is deteriorated by excessive Na, leading to the decrease in the cell efficiency. Its content is preferably 9% or less, more preferably 8% or less, and still more preferably 7% or less.

K₂O: K₂O has the same effects as those in Na₂O, and further has the action of suppressing the change of the CIGS composition in crystal growth of CIGS at a high temperature in the production process of the CIGS solar cell, thereby the decrease in short-circuit current is suppressed. For this reason, it is contained in an amount of from 3.5 to 15%.

However, when its content exceeds 15%, there is a concern that the glass transition temperature is lowered, and the average coefficient of thermal expansion becomes large. Also, there is a concern that the Young's modulus is decreased. The content is preferably 3.8% or more, more preferably 4% or more, and still more preferably 4.2% or more. On the other hand, the content is preferably 12% or less, more preferably 10% or less, and still more preferably 8% or less.

Na₂O and K₂O: For the purpose of sufficiently decreasing the viscosity at a melting temperature of glass and for the purpose of enhancing the cell efficiency of a CIGS solar cell, the total content of Na₂O and K₂O (Na₂O+K₂O) is from 8 to 20%. Na₂O+K₂O is preferably 8.5% or more, more preferably 9% or more, and still more preferably 9.5% or more.

However, when Na₂O+K₂O exceeds 20%, there is a concern that the glass transition temperature excessively decreases. Furthermore, there is a concern that the average coefficient of thermal expansion becomes small. Na₂O+K₂O is preferably 18% or less, more preferably 16% or less, and still more preferably 14% or less.

A ratio of Na₂O to K₂O, Na₂O/K₂O, is 0.7 or more. When the amount of Na₂O is excessively small as compared with the amount of K₂O, there is a concern that the diffusion of Na into the CIGS layer on/above the glass substrate is insufficient, and the cell efficiency is also insufficient. Na₂O/K₂O is preferably 0.8 or more, more preferably 0.9 or more, and still more preferably 1.0 or more.

However, when Na₂O/K₂O exceeds 2.0, there is a concern that the glass transition temperature is excessively lowered. Furthermore, there is a concern that the effect of suppressing the change of the CIGS composition, thereby suppressing the decrease in short-circuit current, in crystal growth at a high temperature in the production process of the CIGS solar cell, by K₂O as described before, is not obtained. For this reason, Na₂O+K₂O is preferably 1.7 or less, more preferably 1.5 or less, and still more preferably 1.4 or less.

MgO, CaO, Na₂O and K₂O: Na₂O is effective for enhancing characteristics of the CIGS layer, CaO is a factor that adversely affects the diffusion of Na, and MgO is a factor that affects the diffusion of Ca. Furthermore, from the matter that the state where Na₂O is larger than K₂O promotes the diffusion of Na₂O by a mixed alkali effect, (2×Na₂O (content mass %)−2×MgO (content mass %)−CaO (content mass %))×(Na₂O (content mass %)/K₂O (content mass %)) is 3 or more for the purpose of the enhancement of the cell efficiency. When this value is smaller than 3, there is a concern that sufficient cell efficiency is not obtained. The value is more preferably 4 or more, still more preferably 4.5 or more, especially preferably 5 or more, and still further preferably 6 or more.

In the case where the amount of Na₂O is too large, there is a concern that the heat resistance, chemical durability and weather resistance are lowered, and in the case where the amount of K₂O is small, there is a concern that the effect of suppressing the change of the CIGS composition, thereby suppressing the decrease in short-circuit current, in crystal growth of CIGS at a high temperature in the production process of the CIGS solar cell is not obtained as described before. For this reason, (2×Na₂O (content mass %)−2×MgO (content mass %)−CaO (content mass %))×(Na₂O (content mass %)/K₂O (content mass %)) is 22 or less. This value is more preferably 18 or less, still more preferably 14 or less, especially preferably 12 or less, and still further preferably 9.5 or less.

The glass substrate for a Cu—In—Ga—Se solar cell of the present invention preferably contains, in terms of mass % on the basis of the following oxides:

from 45 to 70% of SiO₂;

from 11 to 20% of Al₂O₃;

0.5% or less of B₂O₃;

from 0 to 6% of MgO;

from 4 to 12% of CaO;

from 5 to 20% of SrO;

from 0 to 6% of BaO;

from 0 to 8% of ZrO₂;

from 4.5 to 10% of Na₂O; and

from 3.5 to 15% of K₂O;

wherein MgO+CaO+SrO+BaO is from 10 to 30%,

Na₂O+K₂O is from 8 to 20%,

Na₂O/K₂O is from 0.9 to 1.7, and

(2×Na₂O (content mass %)−2×MgO (content mass %)−CaO (content mass %))×(Na₂O (content mass %)/K₂O (content mass %)) is from 5 to 12.

It is more preferred that the glass substrate for a Cu—In—Ga—Se solar cell of the present invention has the above composition, wherein a temperature (T₄) at which a viscosity reaches 10⁴ dPa·s is 1,230° C. or lower, a temperature (T₂) at which a viscosity reaches 10² dPa·s is 1,620° C. or lower, and the relationship between the T₄ and a devitrification temperature (T_{L}) is T₄−T_{L}≧−30° C.

Though the glass substrate for a CIGS solar cell of the present invention is essentially composed of the foregoing base composition, it may contain other components each in an amount of 1% or less and in an amount of 5% or less in total within the range where an object of the present invention is not impaired. For example, there may be the case where ZnO, Li₂O, WO₃, Nb₂O₅, V₂O₅, Bi₂O₃, TiO₂, MoO₃, TlO₂, P₂O₅, and the like may be contained for the purpose of improving the weather resistance, melting properties, devitrification, ultraviolet ray shielding, refractive index, and the like.

Also, for the purpose of improving the melting properties and fining property of glass, SO₃, F, Cl, and SnO₂ may be added into the base composition such that these materials are contained each in an amount of 1% or less and in an amount of 2% or less in total in the glass substrate.

For the purpose of enhancing the chemical durability of glass substrate, Y₂O₃ and La₂O₃ may be contained in an amount of 2% or less in total in the glass substrate.

For the purpose of adjusting the color tone of the glass substrate, colorants such as Fe₂O₃ and TiO₂ may be contained in the glass substrate. A content of such colorants is preferably 1% or less in total.

Considering an environmental load, it is preferable that the glass substrate for a CIGS solar cell of the present invention does not substantially contain As₂O₃ and Sb₂O₃. Also, considering the stable achievement of float forming, it is preferable that the glass substrate does not substantially contain ZnO. However, the glass substrate for a CIGS solar cell of the present invention may be manufactured by forming by a fusion process without limitation to forming by the float process.

### <Manufacturing Method of Glass Substrate for CIGS Solar Cell of the Present Invention>

A manufacturing method of the glass substrate for a CIGS solar cell of the present invention will be described.

In the case of manufacturing the glass substrate for a CIGS solar cell of the present invention, similar to the case of manufacturing conventional glass substrates for a solar cell, a melting/fining step and a forming step are carried out. Since the glass substrate for a CIGS solar cell of the present invention is an alkali glass substrate containing an alkali metal oxide (Na₂O and K₂O), SO₃ can be effectively used as a refining agent, and a float process or a fusion process (down draw process) is suitable as the forming method.

In the manufacturing step of a glass substrate for a solar cell, it is preferable to adopt, as a method for forming a glass into a sheet form, a float process in which a glass substrate with a large area can be formed easily and stably with an increase in size of solar cells.

A preferred embodiment of the manufacturing method of the glass substrate for CIGS solar cell of the present invention will be described.

First of all, a molten glass obtained by melting raw materials is formed into a sheet form. For example, the raw materials are prepared so that the glass substrate to be obtained has a composition as mentioned above, and the raw materials are continuously thrown into a melting furnace, followed by heating at from 1,500 to 1,700° C. to obtain a molten glass. Then, this molten glass is formed into a glass sheet in a ribbon form by applying, for example, a float process.

Subsequently, the glass sheet in a ribbon form is taken out from the float forming furnace, followed by cooling to a room temperature state by cooling means, and cutting to obtain a glass substrate for a CIGS solar cell.

### <Use of Glass Substrate for CIGS Solar Cell of the Present Invention>

The glass substrate for a CIGS solar cell of the present invention is suitable as a glass substrate or cover glass of a CIGS solar cell.

In the case of applying the glass substrate for a CIGS solar cell of the present invention to a glass substrate, a thickness of the glass substrate is preferably 3 mm or less, more preferably 2 mm or less, and still more preferably 1.5 mm or less. A method for providing a CIGS layer on/above the glass substrate is not particularly limited, but a method by a selenization method is particularly preferable. By using the glass substrate for a CIGS solar cell of the present invention, a heating temperature when forming the CIGS layer can be set to from 500 to 700° C., and preferably from 600 to 650° C.

In the case of using the glass substrate for a CIGS solar cell of the present invention for use in only a glass substrate, a cover glass and the like are not particularly limited. Other examples of a composition of the cover glass include soda lime glass and the like.

In the case of using the glass substrate for a CIGS solar cell of the present invention as a cover glass of, a thickness of the cover glass is preferably 3 mm or less, more preferably 2 mm or less, and still more preferably 1.5 mm or less. Also, a method for assembling the cover glass in a glass substrate including a CIGS layer is not particularly limited.

In the case of assembling upon heating using the glass substrate for a CIGS solar cell of the present invention, its heating temperature can be set to from 500 to 700° C., and preferably from 600 to 650° C.

When the glass substrate for a CIGS solar cell of the present invention is used for both a glass substrate and cover glass of a CIGS solar cell, since the average coefficient of thermal expansion within the range of from 50 to 350° C. is equal, thermal deformation or the like does not occur during assembling the solar cell, and thus the case is preferred.

From the characteristics that the expansion coefficient of the glass substrate is close to that of a soda lime glass and a glass transition point is high, the glass substrate for a CIGS solar cell of the present invention can be used in a substrate glass or cover glass of other solar cells. For example, similar to the CIGS solar cell, it is preferably utilized in a glass substrate on which a photoelectric conversion layer of a solar cell of a Cd—Te compound or a solar cell of a Cu—Zn—Sn—S(S is Se or S) compound is to be formed, in which a heating temperature of from 500 to 700° C. is necessary when forming the photoelectric conversion layer.

### <CIGS Solar Cell in the Present Invention>

The solar cell in the present invention is described below.

The solar cell in the present invention has a glass substrate, a cover glass, and a CIGS layer provided as a photoelectric conversion layer between the glass substrate and the cover glass. At least the glass substrate of the glass substrate and the cover glass is the glass substrate for a CIGS solar cell of the present invention.

The solar cell of the present invention will be hereunder described in detail by reference to the accompanying drawings. It should not be construed that the present invention is limited to the accompanying drawings.

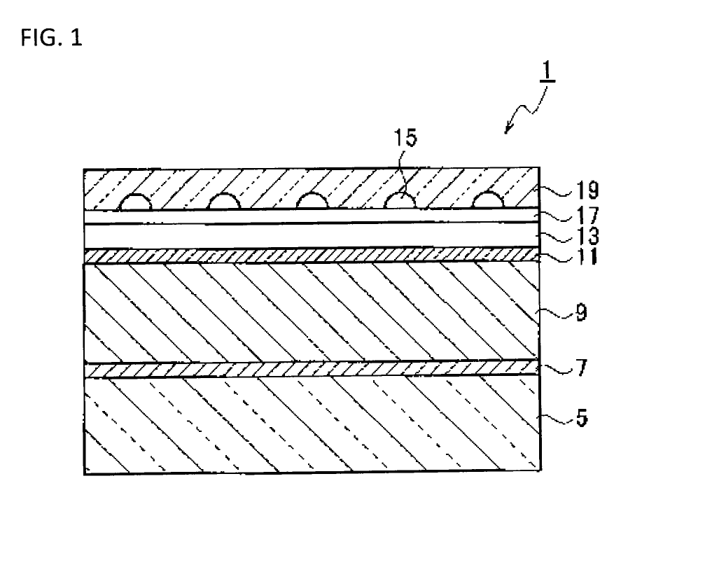

FIG. 1 is a cross-sectional view schematically showing an example of embodiments of the solar cell in the present invention.

In FIG. 1, a CIGS solar cell 1 in the present invention includes a glass substrate 5, a cover glass 19, and a CIGS layer 9 between the glass substrate 5 and the cover glass 19. The glass substrate 5 is preferably composed of the glass substrate for a CIGS solar cell of the present invention as described above. The solar cell 1 includes a back electrode layer of a molybdenum film that is a plus electrode 7 on the glass substrate 5, on which the CIGS layer 9 is provided. As the composition of the CIGS layer, Cu(In₁₋ₓGaₓ)Se₂ can be exemplified. x represents a composition ratio of In and Ga and satisfies a relation of 0<x<1.

On the CIGS layer 9, a CdS (cadmium sulfide) layer, a ZnS (zinc sulfide) layer, a ZnO (zinc oxide) layer, a Zn(OH)₂ (zinc hydroxide) layer, or a mixed crystal layer thereof as a buffer layer 11 is provided. A transparent conductive film 13 of ZnO, ITO, Al-doped ZnO (AZO), or the like is provided through the buffer layer and an extraction electrode such as an Al electrode (aluminum electrode) that is a minus electrode 15, and the like is further provided thereon. An antireflection film may be provided between these layers in a necessary place. In FIG. 1, an antireflection film 17 is provided between the transparent conductive film 13 and the minus electrode 15.

Also, the cover glass 19 may be provided on the minus electrode 15, and if necessary, a gap between the minus electrode and the cover glass is sealed with a resin or adhered with a transparent resin for adhesion. The glass substrate for a CIGS solar cell of the present invention may be used for the cover glass.

In the present invention, end parts of the CIGS layer or end parts of the solar cell may be sealed. Examples of a material for sealing include the same materials as those in the glass substrate for a CIGS solar cell of the present invention and the other glasses and resins.

It should not be construed that a thickness of each layer of the solar cell shown in the accompanying drawings is limited to that shown in the drawing.

### EXAMPLES

The present invention is described in more detail below with reference to the following Examples and Manufacturing Examples, but it should not be construed that the present invention is limited to these Examples and Manufacturing Examples.

Working Examples (Examples 1 to 6 and 10 to 16) of the glass substrate for a CIGS solar cell of the present invention and Comparative Examples (Examples 7 to 9) are described. The numerical values in the parentheses in Table 1 and Table 2 are calculated values.

Raw materials of respective components were made up so as to have a composition shown in Table 1 and Table 2, a sulfate was added to the raw materials in an amount of 0.1 parts by mass in terms of SO₃ per 100 parts by mass of the base composition of raw materials of the components for the glass substrate, followed by heating and melting at a temperature of 1,600° C. for 3 hours using a platinum crucible. In melting, a platinum stirrer was inserted, and stirring was performed for 1 hour, thereby homogenizing the glass. The molten glass was flown out and formed into a sheet form, followed by cooling. Thus, a glass sheet was obtained.

With respect to the glass sheet thus obtained, an average coefficient of thermal expansion (unit: ×10⁻⁷/° C.), a glass transition temperature (unit: ° C.), a density d (unit: g/cm³), a Young's modulus E (unit: GPa), a specific elastic modulus E/d (unit: GPa·cm³/g), a temperature (T₄) at which a viscosity reaches 10⁴ dPa·s (unit: ° C.), a temperature (T₂) at which a viscosity reaches 10² dPa·s (unit: ° C.), a devitrification temperature (T_{L}) (unit: ° C.) and a cell efficiency were measured and shown in Table 1. Measurement method of each property is shown below.

In the Examples, each property of the glass sheet is measured, but each property is the same between the glass sheet and glass substrate. The glass substrate can be obtained by subjecting the obtained glass sheet to processing and polishing.

(1) Tg: Tg is a value measured using a differential thermal expansion meter (TMA) and was determined in conformity with JIS R3103-3 (2001).

(2) Average coefficient of thermal expansion within the range of from 50 to 350° C.: The average value of thermal expansion was measured using a differential thermal expansion meter (TMA) and determined in conformity with JIS R3102 (1995).

(3) Density: About 20 g of a glass block containing no bubbles cut from the glass sheet was measured by Archimedes method.

(4) Young's modulus: With respect to a glass having a thickness of from 7 to 10 mm, the Young's modulus was measured with an ultrasonic pulse method.

(5) Viscosity: The viscosity was measured using a rotary viscometer, and a temperature T₂ (reference temperature for meltability) at which the viscosity η reaches 10² dPa·s and a temperature T₄ (reference temperature for formability) at which the viscosity η reaches 10⁴ dPa·s were measured.

(6) Devitrification temperature (T_{L}): 5 g of a glass block cut from the glass sheet was put on a platinum dish and maintained in an electric furnace at a predetermined temperature for 17 hours. After the temperature maintenance, a maximum value of temperature at which a crystal was not precipitated on and inside the glass block was defined as the devitrification temperature.

(7) Cell efficiency: A solar cell for evaluation was fabricated as shown below using the obtained glass sheet as a substrate for the solar cell and evaluation of the cell efficiency was performed using this. The results are shown in Table 1.

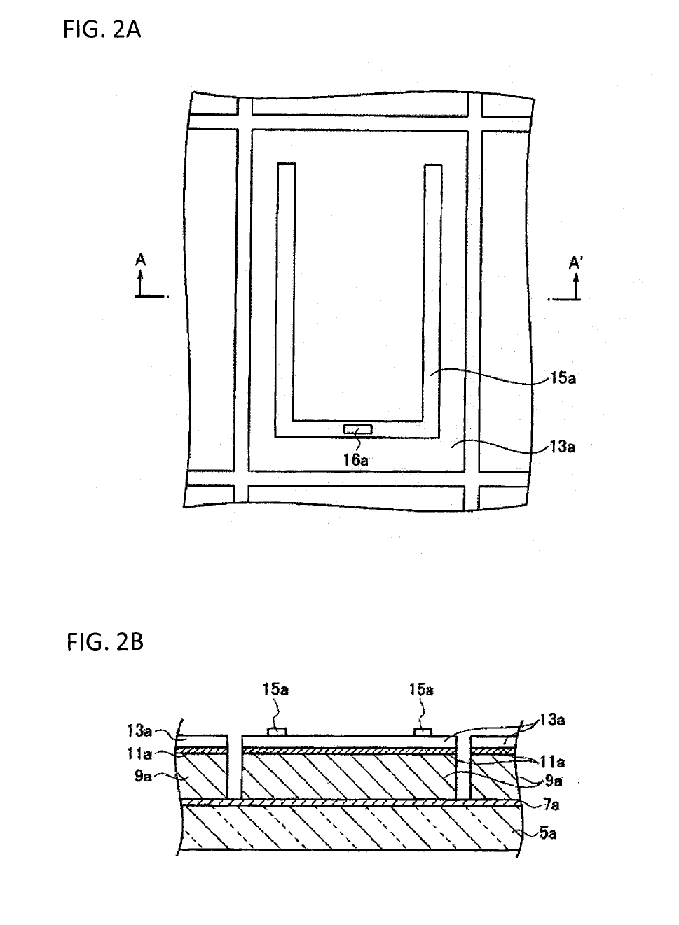

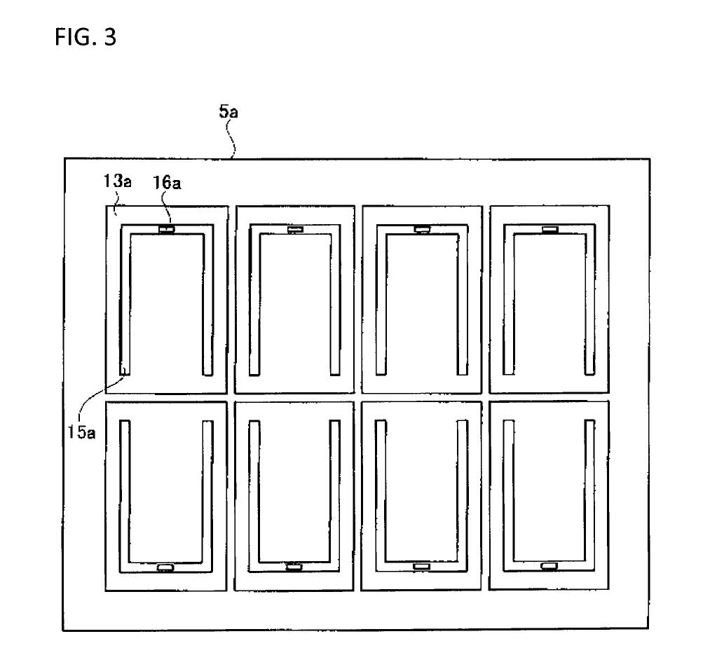

The fabrication of the solar cell for evaluation will be described below with reference to FIGS. 2A, 2B and 3 and reference numerals and signs thereof. The layer configuration of the solar cell for evaluation is almost the same as the layer configuration of the solar cell shown in FIG. 1 except that the cover glass 19 and antireflection film 17 of the solar cell in FIG. 1 are not included.

The obtained glass sheet was processed to have a size of 3 cm×3 cm and a thickness of 1.1 mm, thereby obtaining a glass substrate. An Mo (molybdenum) film was deposited as a plus electrode 7a on the glass substrate 5a by means of a sputtering apparatus. The deposition was carried out at room temperature and the Mo film having a thickness of 500 nm was obtained.

A CuGa alloy layer was deposited on the plus electrode 7a (Mo film) by means of a sputtering apparatus using a CuGa alloy target and subsequently an In layer was deposited using an In target, thereby forming a precursor film of In—CuGa. The deposition was carried out at room temperature. A thickness of each layer was adjusted so that a Cu/(Ga+In) ratio was 0.8 and a Ga/(Ga+In) ratio was 0.25 in the composition of the precursor film measured by fluorescent X-ray, thereby obtaining a precursor film having a thickness of 650 nm.

The precursor film was heat-treated in an argon/hydrogen selenide mixed atmosphere (hydrogen selenide was 5 vol % based on argon; the atmosphere is hereinafter referred to as “selenium atmosphere”) using RTA (Rapid Thermal Annealing) apparatus.

As condition A, as a first stage, the precursor film was held at 500° C. for 10 minutes in the selenium atmosphere to react Cu, In and Ga with Se. Subsequently, as a second stage, the atmosphere was substituted with the hydrogen sulfide atmosphere (hydrogen sulfide was 5 vol % based on argon), and the precursor film was further held at 580° C. for 30 minutes to grow the CIGS crystals. Thus, a CIGS layer 9a was obtained.

As condition B, as a first stage, the precursor film was held at 250° C. for 30 minutes in the selenium atmosphere to react Cu, In and Ga with Se. Subsequently, as a second stage, the atmosphere was substituted with the hydrogen sulfide atmosphere (hydrogen sulfide was 5 vol % based on argon), and the precursor film was further held at 600° C. for 30 minutes to grow the CIGS crystals. Thus, a CIGS layer 9a was obtained.

The thickness of the CIGS layer 9a obtained was 2 μm in both condition A and condition B.

On the CIGS layer 9a, a CdS layer was deposited as a buffer layer 11a by the CBD (Chemical Bath Deposition) process. Specifically, first, cadmium sulfate having a concentration of 0.01M, thiourea having a concentration of 1.0M, ammonia having a concentration of 15M, and pure water were mixed in a beaker. Then, the CIGS layer was dipped in the mixed solution and the beaker with the layer was placed in a constant temperature bath whose water temperature had been set to 70° C. beforehand, thereby forming a CdS layer having a thickness of from 50 to 80 nm.

Furthermore, a transparent conductive film 13a was deposited on the CdS layer by a sputtering apparatus by the following method. First, a ZnO layer was deposited using a ZnO target and then an AZO layer was deposited using an AZO target (a ZnO target containing Al₂O₃ in an amount of 1.5 wt %). The deposition of each layer was carried out at room temperature and a two-layered transparent conductive film 13a having a thickness of 480 nm was obtained.

An aluminum film having a thickness of 1 μm was deposited as a U-shaped minus electrode 15a on the AZO layer of the transparent conductive film 13a by EB deposition method (electrode length of the U-shape: (8 mm in length and 4 mm in width), electrode width: 0.5 mm).

Finally, the resultant was shaven from the transparent conductive film 13a side to the point of the CIGS layer 9a by means of a mechanical scribe, thereby forming a cell as shown in FIG. 2A and FIG. 2B. FIG. 2A is a drawing in which one solar cell is viewed from the top face and FIG. 2B is a cross-sectional view at A-A′ in FIG. 2A. One cell has a width of 0.6 cm and a length of 1 cm, and an area exclusive of the minus electrode 15a was 0.51 cm². As shown in FIG. 3, eight cells in total were obtained on one glass substrate 5a.

The CIGS solar cell for evaluation (the above glass substrate 5a for evaluation on which the eight cells were fabricated) was mounted on a solar simulator (YSS-T80A manufactured by Yamashita Denso Corporation); and a plus terminal (not shown) for the plus electrode 7a previously coated with an InGa solvent and a minus terminal 16a for the lower end of the U shape of the minus electrode 15a were respectively connected to a voltage generator. The temperature within the solar simulator was controlled constant at 25° C. by a temperature regulator. The solar cell was irradiated with a pseudo sun light and, after 60 seconds, the voltage was changed from −1 V to +1V at intervals of 0.015 V, thereby measuring a current value of each of the eight cells.

A cell efficiency was calculated from the current and voltage characteristics during the irradiation according to the following formula (1). Among the eight cells, a value of the cell exhibiting the best efficiency is shown as a value of cell efficiency of each glass substrate in Table 1. The illuminance of the light source used in the test was 0.1 W/cm².

Cell efficiency[%]=Voc[V]×Jsc[A/cm²]×FF(dimensionless)×100/(Illuminance of light source used for the test)[W/cm²] (1)

The cell efficiency is determined by multiplication of an open circuit voltage (Voc), a short-circuit current density (Jsc), and a fill factor (FF).

Here, the open circuit voltage (Voc) is an output when the terminal is opened; the short-circuit current (Isc) is a current when short-circuit is occurred. The short-circuit current density (Jsc) is one obtained by dividing Isc by an area of the cell exclusive of the minus electrode.

Also, a point at which a maximum output is given is called a maximum output point and a voltage at that point is called a maximum voltage value (Vmax) and a current at that point is called a maximum current value (Imax). A value obtained by dividing the product of the maximum voltage value (Vmax) and the maximum current value (Imax) by the product of the open circuit voltage (Voc) and the short-circuit current (Isc) is determined as the fill factor (FF). Using the above value, the cell efficiency was determined.

The residual amount of SO₃ in the glass was from 100 to 500 ppm.

The residual amount of SO₃ in the glass composition was measured by forming a block of the glass cut from the glass sheet into a powdery form and evaluating with fluorescent X-ray.

Fe₂O₃ and TiO₂ were not intentionally contained in the glass of Examples 10 to 16, but the amount unavoidably contained from the raw materials was from 100 to 500 ppm in the glass.

The contents of Fe₂O₃ and TiO₂ in the glass composition were measured by forming a block of the glass cut from the glass sheet into a powdery form and evaluating with fluorescent X-ray.

TABLE 1

| | Ex. 1 | Ex. 2 | Ex. 3 | Ex. 4 | Ex. 5 | Ex. 6 | Ex. 7 | Ex. 8 |
|---|---|---|---|---|---|---|---|---|
| | Working | Working | Working | Working | Working | Working | Comparative | Comparative |
| wt % | Example | Example | Example | Example | Example | Example | Example | Example |
| SiO₂ | 53.0 | 54.2 | 53.3 | 55.8 | 49.6 | 53.0 | 57.0 | 60.9 |
| Al₂O₃ | 12.0 | 12.6 | 13.2 | 12.7 | 15.4 | 13.7 | 7.0 | 9.5 |
| B₂O₃ | 0 | 0 | 0 | 0 | 0 | 0 | 0 | 0 |
| MgO | 0.5 | 0.1 | 0.5 | 1.2 | 0.1 | 0.1 | 2.0 | 5.0 |
| CaO | 6.0 | 5.5 | 5.5 | 5.4 | 4.2 | 5.5 | 2.0 | 6.1 |
| SrO | 11.5 | 11.6 | 9.9 | 7.2 | 14.7 | 13.0 | 9.0 | 1.6 |
| BaO | 3.0 | 1.5 | 1.5 | 1.6 | 0.2 | 1.5 | 8.0 | 0 |
| ZrO₂ | 4.5 | 4.8 | 4.9 | 5.0 | 5.0 | 3.5 | 5.0 | 2.5 |
| Na₂O | 5.5 | 5.8 | 5.8 | 6.3 | 6.9 | 5.8 | 4.0 | 4.9 |
| K₂O | 4.0 | 3.9 | 5.4 | 4.8 | 3.9 | 3.9 | 6.0 | 9.5 |
| MgO + CaO + SrO + BaO | 21.0 | 18.7 | 17.4 | 15.4 | 19.2 | 20.1 | 21.0 | 12.7 |
| Na₂O + K₂O | 9.5 | 9.7 | 11.2 | 11.1 | 10.8 | 9.7 | 10.0 | 14.4 |
| Na₂O/K₂O | 1.38 | 1.49 | 1.07 | 1.31 | 1.77 | 1.49 | 0.67 | 0.52 |
| (2Na₂O − 2MgO − CaO) × | 5.50 | 8.77 | 5.48 | 6.30 | 16.63 | 8.77 | 1.33 | −3.25 |
| (Na₂O/K₂O) | | | | | | | | |
| Average coefficient of thermal | 84 | 83 | 85 | 82 | 84 | 84 | 83 | 84 |
| expansion (×10⁻⁷/° C.) | | | | | | | | |
| Tg (° C.) | 665 | 671 | 665 | 661 | 670 | 662 | 627 | 640 |
| Density d (g/cm³) | 2.81 | 2.77 | 2.75 | 2.70 | 2.80 | 2.78 | 2.81 | 2.55 |
| Young's modulus E (GPa) | 80 | (79) | (78) | (77) | (80) | (79) | 76 | 76 |
| Specific elastic modulus E/d | 28.5 | (28.4) | (28.3) | (28.4) | (28.6) | (28.3) | 27.0 | 29.8 |
| (GPa · cm³/g) | | | | | | | | |
| T₂ (° C.) | 1540 | (1576) | (1564) | (1587) | (1534) | (1553) | 1579 | 1599 |
| T₄ (° C.) | 1172 | (1189) | (1182) | (1193) | (1171) | (1171) | 1182 | 1178 |
| Devitrification temperature T_{L} (° C.) | 1140 | 1150 | 1120 | 1130 | 1180 | 1130 | 1010 | 1186 |
| T₄ − T_{L} (° C.) | 32 | (39) | (62) | (63) | (−9) | (41) | 172 | −8 |
| Cell efficiency (Condition A) | 16.1 | 14.9 | 16.2 | 14.6 | 16.5 | 15.6 | 12.9 | 11.9 |
| Open circuit voltage | 0.62 | 0.61 | 0.63 | 0.60 | 0.62 | 0.59 | 0.59 | 0.56 |
| Short-circuit current | 19.2 | 18.6 | 19.6 | 19.4 | 20.2 | 20.4 | 18.9 | 19.4 |
| FF | 0.69 | 0.67 | 0.67 | 0.64 | 0.67 | 0.66 | 0.59 | 0.56 |
| Cell efficiency (Condition B) | 15.0 | | | | | | 14.0 | 14.0 |
| Open circuit voltage | 0.63 | | | | | | 0.60 | 0.63 |
| Short-circuit current | 17.1 | | | | | | 17.5 | 18 |
| FF | 0.71 | | | | | | 0.68 | 0.63 |

TABLE 2

| | Ex. 9 | Ex. 10 | Ex. 11 | Ex. 12 | Ex. 13 | Ex. 14 | Ex. 15 | Ex. 16 |
|---|---|---|---|---|---|---|---|---|
| | Comparative | Working | Working | Working | Working | Working | Working | Working |
| wt % | Example | Example | Example | Example | Example | Example | Example | Example |
| SiO₂ | 54.6 | 49.0 | 53.5 | 53.4 | 50.6 | 57.0 | 49.9 | 55.5 |
| Al₂O₃ | 16.0 | 16.5 | 13.3 | 14.5 | 13.0 | 11.5 | 14.0 | 12.0 |
| B₂O₃ | 0 | 0.0 | 0.0 | 0.0 | 0.0 | 0.0 | 0.3 | 0.0 |
| MgO | 6.3 | 0.2 | 2.0 | 0.5 | 0.2 | 1.0 | 0.5 | 0.0 |
| CaO | 0.4 | 6.5 | 8.0 | 7.9 | 4.7 | 4.7 | 4.5 | 6.0 |
| SrO | 0 | 7.5 | 5.5 | 7.3 | 12.5 | 8.5 | 9.5 | 10.0 |
| BaO | 0 | 3.5 | 0.0 | 1.9 | 0.7 | 1.8 | 2.3 | 0.5 |
| ZrO₂ | 6.4 | 3.0 | 5.5 | 4.0 | 5.8 | 6.0 | 6.0 | 4.5 |
| Na₂O | 6.5 | 5.8 | 8.0 | 6.0 | 7.0 | 5.2 | 7.0 | 5.0 |
| K₂O | 9.8 | 8.0 | 4.2 | 4.5 | 5.5 | 4.3 | 6.0 | 6.5 |
| MgO + CaO + SrO + BaO | 6.7 | 17.7 | 15.5 | 17.6 | 18.1 | 16.0 | 16.8 | 16.5 |
| Na₂O + K₂O | 16.3 | 13.8 | 12.2 | 10.5 | 12.5 | 9.5 | 13.0 | 11.5 |
| Na₂O/K₂O | 0.66 | 0.73 | 1.90 | 1.33 | 1.27 | 1.21 | 1.17 | 0.77 |
| (2Na₂O − 2MgO − CaO) × | 0.00 | 3.41 | 7.62 | 4.13 | 11.33 | 4.47 | 9.92 | 3.08 |
| (Na₂O/K₂O) | | | | | | | | |
| Average coefficient of thermal | 83 | 92 | 85 | 87 | 91 | 75 | 88 | 8710 |
| expansion (×10⁻⁷/° C.) | | | | | | | | |
| Tg (° C.) | 689 | 659 | 655 | 670 | 651 | 678 | 651 | 670 |
| Density d (g/cm³) | 2.55 | 2.77 | 2.71 | 2.74 | 2.82 | 2.73 | 2.80 | 2.72 |
| Young's modulus E (GPa) | (74) | (75) | (81) | (79) | (78) | (78) | (77) | (76) |
| Specific elastic modulus E/d | (28.8) | (27.1) | (30.0) | (28.8) | (27.7) | (28.6) | (27.5) | (27.9) |
| (GPa · cm³/g) | | | | | | | | |
| T₂ (° C.) | (1693) | (1569) | (1516) | (1563) | (1517) | (1600) | (1541) | (1584) |
| T₄ (° C.) | (1275) | (1182) | (1136) | (1172) | (1152) | (1210) | (1170) | (1193) |
| Devitrification temperature | 1325 | (1060) | (1140) | (1088) | (1174) | (1152) | (1150) | (1117) |
| T_{L} (° C.) | | | | | | | | |
| T₄ − T_{L} (° C.) | (−50) | (122) | (−4) | (84) | (−22) | (58) | (20) | (76) |
| Cell efficiency (Condition A) | 11.3 | 13.2 | 14.5 | 14.0 | 13.7 | 14.7 | 13.9 | 14.3 |
| Open circuit voltage | 0.62 | 0.56 | 0.60 | 0.60 | 0.58 | 0.63 | 0.61 | 0.64 |
| Short-circuit current | 15.0 | 20.3 | 19.2 | 18.3 | 18.6 | 18.3 | 19.1 | 18.4 |
| FF | 0.62 | 0.59 | 0.64 | 0.65 | 0.65 | 0.65 | 0.61 | 0.62 |
| Cell efficiency (Condition B) | | 15.3 | 14.5 | | 16.7 | 15.7 | 14.4 | 15.1 |
| Open circuit voltage | | 0.57 | 0.59 | | 0.62 | 0.58 | 0.59 | 0.6 |
| Short-circuit current | | 21.7 | 18.4 | | 19.4 | 17.5 | 17.8 | 16.7 |
| FF | | 0.63 | 0.68 | | 0.71 | 0.79 | 0.7 | 0.77 |

As is apparent from Table 1 and Table 2, the glass sheets in the working examples (Examples 1 to 6 and 10 to 16) satisfy that the glass transition temperature Tg is high as 640° C. or higher, the average coefficient of thermal expansion is from 60×10⁻⁷ to 110×10⁻⁷/° C., and the density is 2.9 g/cm³ or less, and thus have the characteristics of the glass substrate for a solar cell in good balance. Furthermore, the glass sheet in the working example (Example 1) had high cell efficiency in both Condition A and Condition B.

The cell efficiency of the glass sheets other than Example 1 also shows good result. In the glass in Examples 1 to 6 and 10 to 16, SrO is from 5 to 20%, Na₂O is from 4.5 to 10%, K₂O is from 3.5 to 15%, Na₂O/K₂O is from 0.7 to 2.0, and (2×Na₂O (content mass %)−2×MgO (content mass %)−CaO (content mass %))×(Na₂O (content mass %)/K₂O (content mass %)) is from 3 to 22. Therefore, the cell efficiency is high.

Therefore, high cell efficiency, high glass transition temperature and a predetermined average coefficient of thermal expansion can be satisfied in good balance. As a result, the CIGS photoelectric conversion layer does not peel from the glass substance with the Mo film. Furthermore, when fabricating a solar cell in the present invention (specifically, when laminating a glass substrate having a CIGS photoelectric conversion layer and a cover glass by heating), the glass substrate is difficult to be deformed, and the cell efficiency is further excellent.

On the other hand, as shown in Table 1 and Table 2, in the glass sheet in the comparative example (Example 7), Tg is low, and the glass sheet is easy to be deformed during the deposition at 600° C. or higher. Furthermore, because Na₂O/K₂O and (2Na₂O-2MgO—CaO)×(Na₂O/K₂O) are low and additionally BaO is large, the cell efficiency is poor.

In the glass sheet in the comparative example (Example 8), because Na₂O/K₂O and (2Na₂O-2MgO—CaO)×(Na₂O/K₂O) are low and additionally SrO is small, the cell efficiency is poor.

In the glass sheet in the comparative example (Example 9), because Na₂O/K₂O and (2Na₂O-2MgO—CaO)×(Na₂O/K₂O) are low, SrO is small and MgO is too large, the cell efficiency is poor.

The glass substrate for a Cu—In—Ga—Se solar cell of the present invention is suitable as a glass substrate for a solar cell of CIGS. Furthermore, the glass substrate can be used in a cover glass for a CIGS solar cell, and substrates and cover glasses of other solar cells.

While the invention has been described in detail and with reference to specific embodiments thereof, it will be apparent to one skilled in the art that various changes and modifications can be made therein without departing from the spirit and scope thereof.

This application is based on Japanese Patent Application No. 2012-050060 filed on Mar. 7, 2012, the entire subject matter of which is incorporated herein by reference.

### INDUSTRIAL APPLICABILITY

The glass substrate for a Cu—In—Ga—Se solar cell of the present invention can have the characteristics of high cell efficiency, high glass transition temperature, a prescribed average coefficient of thermal expansion, high glass strength, low glass density, meltability and formability during production of a sheet glass, and prevention of devitrification in good balance, and can provide a solar cell having high cell efficiency by using the glass substrate for a CIGS solar cell of the present invention.

### EXPLANATION OF LETTER AND NUMERALS

1: Solar cell
5, 5a: Glass substrate
7, 7a: Plus electrode
9, 9a: CIGS layer
11, 11a: Buffer layer
13, 13a: Transparent conductive film
15, 15a: Minus electrode
17: Antireflection film
19: Cover glass

1. A glass substrate for a Cu—In—Ga—Se solar cell, comprising, in terms of mass % on the basis of the following oxides:
from 45 to 70% of SiO₂;
from 11 to 20% of Al₂O₃;
0.5% or less of B₂O₃;
from 0 to 6% of MgO;
from 4 to 12% of CaO;
from 5 to 20% of SrO;
from 0 to 6% of BaO;
from 0 to 8% of ZrO₂;
from 4.5 to 10% of Na₂O; and
from 3.5 to 15% of K₂O;
wherein MgO+CaO+SrO+BaO is from 10 to 30%,
Na₂O+K₂O is from 8 to 20%,
Na₂O/K₂O is from 0.7 to 2.0,
(2×Na₂O (content mass %)−2×MgO (content mass %)−CaO (content mass %))×(Na₂O (content mass %)/K₂O (content mass %)) is from 3 to 22, and
the glass substrate has a glass transition temperature of from 640 to 700° C., an average coefficient of thermal expansion of from 60×10⁻⁷ to 110×10⁻⁷/° C., and a density of from 2.45 to 2.9 g/cm³.

2. The glass substrate for a Cu—In—Ga—Se solar cell according to claim 1, wherein Na₂O/K₂O is from 0.9 to 1.7, and (2×Na₂O (content mass %)−2×MgO (content mass %)−CaO (content mass %))×(Na₂O (content mass %)/K₂O (content mass %)) is from 5 to 12.

3. The glass substrate for a Cu—In—Ga—Se solar cell according to claim 1, wherein Na₂O/K₂O is from 1.0 to 1.5, and (2×Na₂O (content mass %)−2×MgO (content mass %)−CaO (content mass %))×(Na₂O (content mass %)/K₂O (content mass %)) is from 6 to 9.5.

4. The glass substrate for a Cu—In—Ga—Se solar cell according to claim 1, comprising:
from 0 to 2.5% of MgO;
from 5.5 to 18% of SrO; and
from 0 to 4% of BaO.

5. The glass substrate for a Cu—In—Ga—Se solar cell according to claim 1, comprising:
from 11.5 to 16% of Al₂O₃;
from 0 to 1.5% of MgO;
from 4.5 to 8% of CaO;
from 7 to 15% of SrO; and
from 0 to 2% of BaO.

6. The glass substrate for a Cu—In—Ga—Se solar cell according to claim 1, having the glass transition temperature of from 660 to 690° C., the average coefficient of thermal expansion of from 70×10⁻⁷ to 95×10⁻⁷/° C., and the density of from 2.6 to 2.8 g/cm³.

7. The glass substrate for a Cu—In—Ga—Se solar cell according to claim 1, having a temperature (T₄) at which a viscosity reaches 10⁴ dPa·s of 1,230° C. or lower, a temperature (T₂) at which a viscosity reaches 10² dPa·s of 1,620° C. or lower, and a relationship between the temperature T₄ and a devitrification temperature (T_{L}) of T₄−T_{L}≧−30° C.

8. A solar cell comprising a glass substrate, a cover glass and a photoelectric conversion layer of Cu—In—Ga—Se provided between the glass substrate and the cover glass,
wherein at least the glass substrate of the glass substrate and the cover glass is the glass substrate for a Cu—In—Ga—Se solar cell according to claim 1.
